(19) United States
(12) Patent Application Publication
(10) Pub. No.: US 2024/0136205 A1
(43) Pub. Date: Apr. 25, 2024

(54) SUBSTRATE PROCESSING APPARATUS AND SUBSTRATE PROCESSING METHOD

(71) Applicant: Tokyo Electron Limited, Tokyo (JP)

(72) Inventor: Kenji FUKUSHIMA, Koshi City (JP)

(21) Appl. No.: 18/489,188

(22) Filed: Oct. 17, 2023

(30) Foreign Application Priority Data
Oct. 19, 2022 (JP) 2022-168326

(51) Int. Cl. H01L 21/67; C03C 15/00

(52) U.S. Cl. CPC H01L 21/67023; C03C 15/00

(57) ABSTRACT

A substrate processing apparatus includes: a processing container; a substrate holder that horizontally holds the substrate inside the processing container; a liquid supplier that supplying a processing liquid to a lower surface of the substrate; a cover that discharges a gas toward an upper surface of the substrate; a gas supplier that supplies the gas to the cover; a heater that heats the gas; and a controller. The controller performs a control to: maintain a temperature of the heater at a second set temperature while the processing liquid is supplied to the lower surface; maintain the temperature of the heater at the first set temperature during a standby operation; and increase an output of the heater during the standby operation and raise the temperature of the heater from the first set temperature to the second set temperature until a subsequent substrate is loaded in the standby operation.

### CROSS-REFERENCE TO RELATED APPLICATION

This application is based upon and claims the benefit of priority from Japanese Patent Application No. 2022-168326, filed on Oct. 20, 2022, the entire contents of which are incorporated herein by reference.

### TECHNICAL FIELD

The present disclosure relates to a substrate processing apparatus and a substrate processing method.

### BACKGROUND

A substrate processing apparatus disclosed in Patent Document 1 includes a substrate rotation holder that rotates a substrate while horizontally holding the substrate, and a processing liquid supplier that supplies a processing liquid to a lower surface of the substrate held by the substrate rotation holder.

### PRIOR ART DOCUMENT

### Patent Document

Patent Document 1: Japanese Laid-Open Patent Publication No. 2016-143790

### SUMMARY

According to one embodiment of the present disclosure, there is provided a substrate processing apparatus including: a processing container in which a loading/unloading port for a substrate is provided; a substrate holder configured to horizontally hold the substrate inside the processing container; a liquid supplier configured to supply a processing liquid to a lower surface of the substrate held by the substrate holder; a cover provided with a gas outlet configured to discharge a gas toward an upper surface of the substrate held by the substrate holder; a gas supplier configured to supply the gas to the cover; a heater provided in the cover to heat the gas; and a controller, wherein the controller is configured to perform a control to: maintain a temperature of the heater at a second set temperature higher than a first set temperature while the processing liquid is supplied to the lower surface of the substrate; maintain the temperature of the heater at the first set temperature during a standby operation from when the substrate begins to be unloaded from the processing container until a subsequent substrate is loaded into the processing container; and increase an output of the heater during the standby operation and raise the temperature of the heater from the first set temperature to the second set temperature until the subsequent substrate is loaded into the processing container.

### BRIEF DESCRIPTION OF DRAWINGS

The accompanying drawings, which are incorporated in and constitute a part of the specification, illustrate embodiments of the present disclosure, and together with the general description given above and the detailed description of the embodiments given below, serve to explain the principles of the present disclosure.

FIG. 1 is a cross-sectional view illustrating an example of a substrate processing apparatus according to an embodiment.

FIG. 2 is a cross-sectional view illustrating an example of a flow of a gas and a processing liquid in the substrate processing apparatus of FIG. 1.

FIG. 3 is a flowchart illustrating an example of a substrate processing method according to an embodiment.

FIG. 4 is a timing chart illustrating an example of an operation of the substrate processing apparatus.

FIG. 5A is a diagram illustrating a first example of control of a temperature-rise time period, and FIG. 5B is a diagram illustrating a second example of the control of the temperature-rise time period.

FIG. 6 is a diagram illustrating an example of a change in a first set temperature.

FIG. 7 is a cross-sectional view illustrating a flow of a gas and a processing liquid in a substrate processing apparatus according to a first modification.

FIG. 8 is a cross-sectional view illustrating a flow of a gas and a processing liquid in a substrate processing apparatus according to a second modification.

### DETAILED DESCRIPTION

Hereinafter, embodiments of the present disclosure will be described with reference to the accompanying drawings. In the following detailed description, numerous specific details are set forth in order to provide a thorough understanding of the present disclosure. However, it will be apparent to one of ordinary skill in the art that the present disclosure may be practiced without these specific details. In other instances, well-known methods, procedures, systems, and components have not been described in detail so as not to unnecessarily obscure aspects of the various embodiments. In addition, in each drawing, the same reference numerals will be given to the same or corresponding components, and descriptions thereof may be omitted. In the present specification, an X-axis direction, a Y-axis direction, and a Z-axis direction are directions perpendicular to each other. The X-axis direction and the Y-axis direction are horizontal directions, and the Z-axis direction is a vertical direction.

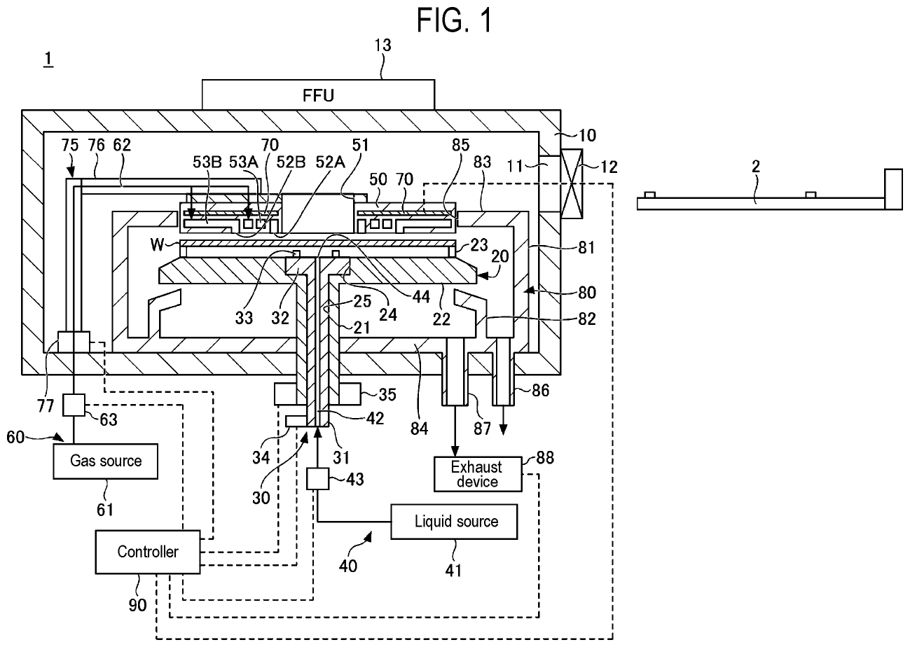

Referring to FIG. 1, a substrate processing apparatus 1 according to an embodiment will be described. The substrate processing apparatus 1 includes a processing container 10, a substrate holder 20, a rotation drive 35, a liquid supplier 40, a cover 50, a gas supplier 60, a heater 70, a cover lifter 75, a collecting cup 80, and a controller 90.

The processing container 10 accommodates a substrate W. A loading/unloading port 11 for the substrate W is formed in a sidewall of the processing container 10. A gate valve 12 opens and closes the loading/unloading port 11 under a control of the controller 90. A fan filter unit (FFU) 13 is provided on a ceiling of the processing container 10. The FFU 13 is an example of a down-flow creator that creates a down-flow inside the processing container 10.

The substrate W is a semiconductor substrate such as a silicon wafer, or a glass substrate. The substrate W is loaded into an interior of the processing container 10 via the loading/unloading port 11 by a transfer device 2. After being processed with a processing liquid, the substrate W is unloaded from the processing container 10 via the loading/unloading port 11 by the transfer device 2.

The substrate holder 20 horizontally holds the substrate W inside the processing container 10. The substrate holder 20 includes a rotational shaft 21 and a base plate 22. The rotational shaft 21 extends vertically. The rotational shaft 21 is formed in a hollow cylindrical shape. The base plate 22 is provided on an upper end of the rotational shaft 21. The base plate 22 is circular in a plan view. A diameter of the base plate 22 is greater than that of the rotational shaft 21. The base plate 22 is formed concentrically with the rotational shaft 21.

The substrate holder 20 includes a plurality of support pins 23. The plurality of support pins 23 are provided on an upper surface of the base plate 22. The plurality of support pins 23 are brought into contact with a lower surface of the substrate W to support the substrate W. In addition, the substrate holder 20 may include a plurality of claws instead of the plurality of support pins 23. The plurality of claws hold a periphery of the substrate W.

A recess 24 is formed in a central portion of the upper surface of the base plate 22. The recess 24 has a circular shape in a plan view. An insertion bore 25 is formed in the base plate 22 and the rotational shaft 21 to communicate with a bottom surface of the recess 24. A lifting shaft 31 of a substrate relay 30 is inserted into the insertion bore 25.

The substrate relay 30 includes the lifting shaft 31, a lifting plate 32, lifting pins 33, and a lifting drive 34. The lifting plate 32 is provided on the top of the lifting shaft 31. The lifting plate 32 has a circular shape in a plan view. The lifting pins 33 are provided on an upper surface of the lifting plate 32. The lifting pins 33 are brought into contact with the lower surface of the substrate W to support the substrate W. A length of each lifting pin 33 is shorter than that of the support pin 23.

The lifting drive 34 raises and lowers the lifting plate 32 between a lowered position (see FIG. 1) and a raised position to mediate the substrate W between the substrate holder 20 and the transfer device 2. The lifting drive 34 includes a motor, a ball screw that converts a rotational motion of the motor into a linear motion of the lifting shaft 31, and the like. In addition, the lifting drive 34 may also be configured with a pneumatic cylinder or the like.

The lifting plate 32 is accommodated in the recess 24 of the base plate 22 at the lowered position. At this time, the lifting pins 33 are located lower than the lower surface of the substrate W held by the substrate holder 20. On the other hand, when the lifting plate 32 is located at the raised position, the substrate W supported by the lifting pins 33 is located higher than the collecting cup 80.

The rotation drive 35 rotates the substrate holder 20. The rotation drive 35 rotates the rotational shaft 21 to rotate the substrate holder 20. The rotation drive 35 includes a deceleration mechanism, a motor and the like. A rotational motion of the motor is transmitted to the rotational shaft 21 through the deceleration mechanism and the like.

The liquid supplier 40 supplies the processing liquid to the lower surface of the substrate W held by the substrate holder 20. The processing liquid may be a chemical liquid such as an etching liquid. The liquid supplier 40 may sequentially supply, to the lower surface of the substrate W held by the substrate holder 20, the processing liquid and a rinsing liquid for removing the processing liquid from the substrate W. The rinsing liquid may be deionized water (DIW) or the like.

The liquid supplier 40 includes a liquid source 41, a liquid supply pipe 42, and a flow-rate adjuster 43. The liquid supply pipe 42 is provided in the lifting shaft 31 and the lifting plate 32. The liquid supply pipe 42 discharges the processing liquid or the rinsing liquid toward the lower surface of the substrate W from a supply port 44 formed at an upper end of the liquid supply pipe 42. The processing liquid and the rinsing liquid may be discharged from different supply ports 44. The flow-rate adjuster 43 is provided in a pipe, which delivers the processing liquid or the rinsing liquid from the liquid source 41 to the liquid supply pipe 42, to adjust a flow rate of the processing liquid or the rinsing liquid. The flow-rate adjuster 43 includes a flow-rate adjustment valve, an on/off valve and the like.

The cover 50 is provided to face then upper surface of the substrate W held by the substrate holder 20. The cover 50 has an annular shape. An opening 51 is formed in a central portion of the cover 50 so as to vertically pass through the cover 50. A diameter of the cover 50 is substantially the same as that of the substrate W. The cover 50 is provided with gas outlets 52A and 52B.

The gas outlets 52A and 52B are provided outside the opening 51. The gas outlets 52A and 52B discharge a gas toward the upper surface of the substrate W. The gas outlets 52A and 52B discharge the gas directly downward but may also discharge the gas in an obliquely downward direction. Specifically, the expression “obliquely downward direction” refers to a direction that is inclined outward in a radial direction of the substrate W as it goes downward. This promotes the gas to flow outward in the radial direction of the substrate W.

The gas outlet 52A and the gas outlet 52B are provided at an interval in the radial direction of the substrate W. Hereinafter, the gas outlet 52A may be referred to as a first gas outlet 52A, and the gas outlet 52B may be referred to as a second gas outlet 52B. The second gas outlet 52B is provided outside the first gas outlet 52A in the radial direction of the substrate W. A plurality of first gas outlets 52A and a plurality of second gas outlets 52B are provided at equal intervals along a circumferential direction of the substrate W, respectively.

The cover 50 includes gas flow paths 53A and 53B provided therein. Hereinafter, the gas flow path 53A may be referred to as a first gas flow path 53A, and the gas flow path 53B may be referred to as a second gas flow path 53B. The first gas outlet 52A is provided at a distal end of the first gas flow path 53A, and the second gas outlet 52B is provided at a distal end of the second gas flow path 53B.

The first gas flow path 53A and the second gas flow path 53B are provided step by step in the radial direction of the substrate W. The second gas flow path 53B is provided outside the first gas flow path 53A in the radial direction of the substrate W. Each of the first gas flow path 53A and the second gas flow path 53B has a bent wall. Such a bent wall may increase a contact area between the cover 50 and the gas, which makes it possible to improve a heating efficiency of the gas.

The gas supplier 60 supplies the gas to the cover 50. The gas supplier 60 includes a gas source 61, a gas pipe 62, and a flow-rate adjuster 63. The gas pipe 62 sends the gas from the gas source 61 to the cover 50. The flow-rate adjuster 63 is provided in the gas pipe 62 to adjust a flow rate of the gas. The flow-rate adjuster 63 includes a flow-rate adjustment valve, an on/off valve and the like. The flow-rate adjuster 63 is capable of independently adjusting the flow rate of the first gas flow path 53A and the flow rate of the second gas flow path 53B.

The heater 70 is provided in the cover 50 to heat the gas. The heated gas is discharged to the upper surface of the substrate W to heat the substrate W. The heater 70 is, for example, a sheath heater. The heater 70 is provided inside the cover 50. The heater 70 is provided at upper side of the gas flow paths 53A and 53B, but may be provided at lower sides of the gas flow paths 53A and 53B. Alternatively, the heater 70 may be provided at both the upper and lower sides.

The cover lifter 75 raises and lowers the cover 50 between a processing position (see FIG. 1) where the cover is located while the processing liquid is supplied to the lower surface of the substrate W and a standby position above the processing position. The cover lifter 75 includes an arm 76 that supports the cover 50, and an arm drive 77 that raises and lowers the arm 76. The arm drive 77 is also capable of swiveling the arm 76.

The collecting cup 80 collects the processing liquid supplied to the substrate W. The collecting cup 80 is provided to cover the surrounding of the base plate 22. The collecting cup 80 includes a first wall portion 81, a second wall portion 82, a ceiling portion 83, and a bottom portion 84. The first wall portion 81 is formed in an annular shape. The first wall portion 81 is formed outward of the base plate 22. The second wall portion 82 is formed in an annular shape. The second wall portion 82 is formed inward of the first wall portion 81. The second wall portion 82 is formed to prevent the processing liquid from flowing inward of the second wall portion 82 and to allow the processing liquid to flow outward of the second wall portion 82.

The ceiling portion 83 is formed to protrude inward from an upper end of the first wall portion 81. An opening 85 is formed in the ceiling portion 83 so as to vertically pass through the ceiling portion 83. The opening 85 has a circular shape in a plan view. A diameter of the opening 85 is greater than those of the substrate W and the cover 50. The substrate W and the cover 50 are vertically movable in the opening 85.

The bottom portion 84 is connected to a drain pipe 86 and an exhaust pipe 87. The drain pipe 86 is positioned outward of the second wall portion 82 to discharge the processing liquid or the rinsing liquid to the outside. The exhaust pipe 87 is positioned inward of the second wall portion 82 to discharge the gas to the outside. The exhaust pipe 87 is connected to an exhaust device 88. The exhaust device 88 includes a pump and the like.

The controller 90 is, for example, a computer, and includes a computing element such as a central processing unit (CPU), and a storage 502 such as a memory. The storage stores programs for controlling various processes executed in the substrate processing apparatus 1. The controller 90 causes the processor to execute the programs stored in the storage, thus controlling the operation of the substrate processing apparatus 1.

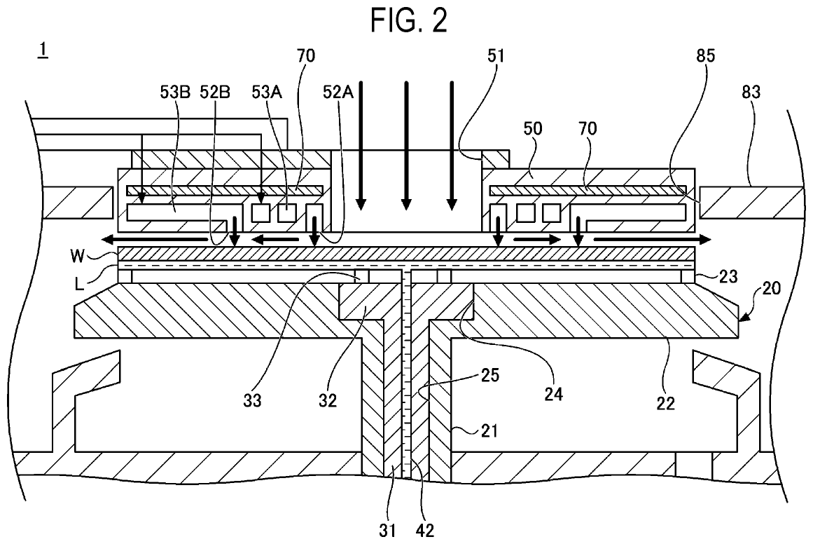

Next, an example of a flow of the gas and the processing liquid in the substrate processing apparatus 1 will be described with reference to FIG. 2. In the substrate processing apparatus 1, residues of the processing liquid L may adhere to the substrate W as particles. To cope with this situation, the substrate processing apparatus 1 includes the FFU 13. The FFU 13 creates a down-flow inside the processing container 10 to prevent floating of the particles.

The creation of the down-flow allows the gas to flow toward the central portion of the substrate W from the opening 51 of the cover 50, thus stabilizing a swirl flow of the gas in a gap between the substrate W and the cover 50. The swirl flow of the gas is oriented outward in the radial direction of the substrate W toward the rotational direction of the substrate W, thus discharging the particles outward of the substrate W.

Further, the creation of the down-flow allows the gas to flow toward the central portion of the substrate W from the opening 51 of the cover 50, thus preventing the generation of a negative pressure in the central portion of the substrate W. This prevents the central portion of the substrate W from being convexly curved due to the negative pressure, which prevents the substrate W and the cover 50 from coming into contact with each other.

However, the temperature of the substrate W may be lowered due to the creation of the down-flow. A processing rate (e.g., etching rate) by the processing liquid L may be reduced with a drop in the temperature of the substrate W. Further, the swirl flow of the gas may cause a variation in the temperature of the substrate W in the radial direction of the substrate W. Such a variation in the temperature of the substrate W leads to a variation in the processing rate.

The heater 70 is provided in the cover 50 to heat the gas. The heated gas is discharged toward the upper surface of the substrate W, thus heating the substrate W. This may prevent a reduction in the processing rate. The heater 70 is also capable of improving the in-plane temperature uniformity of the substrate W and capable of reducing a variation in the processing rate.

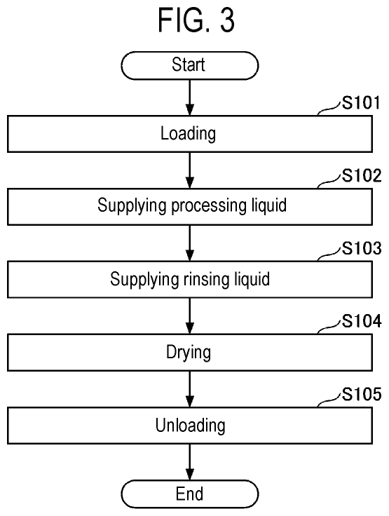

Next, a substrate processing method according to an embodiment will be described with reference to FIG. 3. The substrate processing method includes steps S101 to S105 illustrated in FIG. 3. Steps S101 to S105 are performed under the control of the controller 90.

First, the transfer device 2 loads the substrate W into the processing container 10 (step S101). The substrate W is delivered from the transfer device 2 to the substrate holder 20 by the substrate relay 30. Once the substrate holder 20 holds the substrate W, the loading of the substrate W into the processing container 10 is completed.

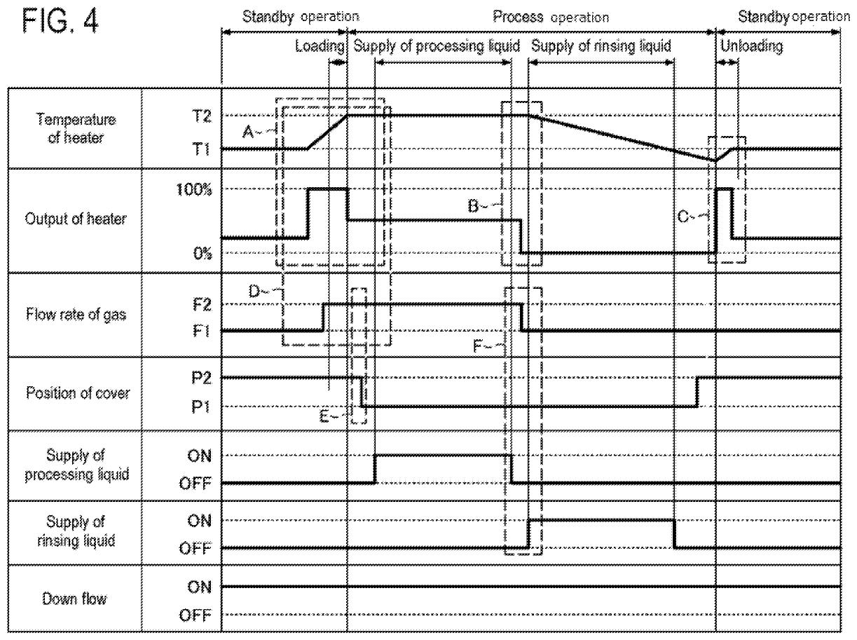

After the loading of the substrate W is completed, the cover lifter 75 lowers the cover 50 from a standby position P2 to a processing position P1 (see FIG. 4). Further, after the loading of the substrate W is completed, the rotation drive 35 rotates the substrate W together with the substrate holder 20.

Subsequently, the liquid supplier 40 supplies the processing liquid L to the lower surface of the substrate W (step S102). The processing liquid L is supplied to the central portion of the lower surface of the substrate W which is rotating, and flows outward in the radial direction of the substrate W by virtue of a centrifugal force so that the processing liquid L soaks and spreads over the entire lower surface of the substrate W. Thereafter, the liquid supplier 40 stops the supply of the processing liquid L.

Subsequently, the liquid supplier 40 supplies the rinsing liquid to the lower surface of the substrate W (step S103). The rising liquid is supplied to the central portion of the lower surface of the substrate W which is rotating, and flows outward in the radial direction of the substrate W by virtue of the centrifugal force so that the rinsing liquid soaks and spreads over the entire lower surface of the substrate W while replacing the processing liquid L. Thereafter, the liquid supplier 40 stops the supply of the rinsing liquid.

Subsequently, the rotation drive 35 continuously rotates the substrate W together with the substrate holder 20 to dry the substrate W (step S104). Thereafter, the rotation drive 35 stops the rotation of the substrate holder 20, and the substrate holder 20 releases the holding of the substrate W.

Subsequently, the transfer device 2 unloads the substrate W to the interior of the processing container 10 (step S105). After the substrate W is delivered to the transfer device 2 from the substrate holder 20 by the substrate relay 30, the substrate W is unloaded by the transfer device 2.

Hereinafter, a time period from when an n^{th} (n is an integer of 1 or more) substrate W is loaded until the n^{th} substrate W begins to be unloaded may be referred to as a process operation. The process operation refers to a time period from when the substrate holder 20 initiates the holding of the n^{th} substrate W until when the substrate holder 20 releases the holding of the n^{th} substrate W.

Further, a time period other than that spent in the process operation may be referred to as a standby operation. The standby operation refers to a time period from when the unloading of the n^{th} substrate W begins until when the loading of a (n+1)^{th} substrate W is completed. The standby operation may also be a time period from when the substrate processing apparatus 1 is powered on until when the loading od the n^{th} substrate W is completed.

Next, an example of an operation timing of the substrate processing apparatus 1 will be described with reference to FIG. 4. As illustrated by the dashed line A in FIG. 4, the controller 90 performs a control to maintain the temperature of the heater 70 at a first set temperature T1 during the standby operation and maintain the temperature of the heater 70 at a second set temperature T2 (T2>T1) while the processing liquid L is supplied. In the standby operation, since the substrate W is not processed, it is not necessary to heat the substrate W. By limiting the output of the heater 70 during the standby operation, it is possible to reduce power consumption.

Further, as illustrated by the dashed line A in FIG. 4, the controller 90 performs a control to increase the output of the heater 70 during the standby operation, thus raising the temperature of the heater 70 from the first set temperature T1 to the second set temperature T2 before the loading of the substrate W is completed. By rising the temperature of the heater 70 before the loading of the substrate W is completed, it is possible to quickly begin the supply of the processing liquid L to the lower surface of the substrate W, which makes it possible to suppress a reduction in the processing efficiency of the substrate W.

The controller 90 determines a time at which the temperature of the heater 70 begins to raise from the first set temperature T1 to the second set temperature T2 such that a time period from the completion of the rise in the temperature of the heater 70 to the completion of the loading of the substrate W falls within a set period of time (preferably, becomes zero). The controller 90 acquires a processing plan for the substrate W from a host computer or the like, and calculates a time at which the loading of the substrate W is completed with reference to the processing plan. The controller 90 determines the time at which the temperature of the heater 70 begins to raise from the first set temperature T1 to the second set temperature T2 based on the time at which the loading of the substrate W is completed.

As illustrated by the dashed line B in FIG. 4, the controller 90 performs a control to decrease the output of the heater 70 after completing (and at the same time as) the supply of the processing liquid L and before initiating (and at the same time as) the supply of the rinsing liquid, thus lowering the temperature of the heater 70 from the second set temperature T2. The output of the heater 70 may be maintained at zero during the supply of the rinsing liquid.

The rinsing liquid removes the processing liquid L from the substrate W. While the processing liquid L reacts with the substrate W, the rinsing liquid does not react with the substrate W. This eliminates a need to control a reaction rate relating to the rinsing liquid. By decreasing the output of the heater 70 after completing the supply of the processing liquid L and before initiating the supply of the rinsing liquid, it is possible to reduce power consumption while maintaining a processing quality of the substrate W.

In addition, in FIG. 4, a delay time exists between the completion of the supply of the processing liquid L and the initiation of the supply of the rinsing liquid. However, the delay time may be omitted. The completion of the supply of the processing liquid L, the initiation of the supply of the rinsing liquid, and the decreasing the output of the heater 70 may be performed in a simultaneous manner.

As illustrated by the dashed line C in FIG. 4, the controller 90 performs a control to increase the output of the heater 70 within a set period of time from the initiation of the standby operation (particularly, at the same time as the initiation of the standby operation), thus returning the temperature of the heater 70 to the first set temperature T1. By returning the temperature of the heater 70, which was lowered during the supply of the rinsing liquid, to the first set temperature T1, it is possible to raise the temperature of the heater 70 to the second set temperature T2 within a certain period of time in a subsequent operation. This makes it possible to prepare the loading of the subsequent substrate W.

As illustrated by the dashed line D in FIG. 4, the controller 90 performs a control to maintain a discharge flow rate of the gas at a first set flow rate F1 during the standby operation and maintain the discharge flow rate of the gas at a second set flow rate F2 (F2>F1) during the supply of the processing liquid L. In the standby operation, since no processing is performed on the substrate W, it is not necessary to heat the substrate W. By limiting the discharge flow rate of the gas during the standby operation, it is possible to reduce the usage of the gas.

As illustrated by the dashed line D in FIG. 4, the controller 90 performs a control to increase the discharge flow rate of the gas, which is used to heat the substrate W, from the first set flow rate F1 to the second set flow rate F2 while increasing the temperature of the heater 70 from the first set temperature T1 to the second set temperature T2. When the discharge flow rate of the gas varies after the temperature of the heater 70 is stabilized, a variation in the temperature of the heater 70 may occur. By increasing the discharge flow rate of the gas before the temperature of the heater 70 is stabilized, it is possible to stabilize the temperature of the heater 70 in a short period of time.

As illustrated by the dashed line E in FIG. 4, the controller 90 performs a control to lower the cover 50 from the standby position P2 to the processing position P1 in a state where the discharge flow rate of the gas is maintained at the second set flow rate F2. Once the temperature of the heater 70 is stabilized, the gas may be discharged to the upper surface of the substrate W through the cover 50 so that the temperature of the substrate W is easily stabilized at a desired temperature.

As illustrated by the dashed line F in FIG. 4, the controller 90 performs a control to decrease the discharge flow rate of the gas from the second set flow rate F2 to the first set flow rate F1 after completing the supply of the processing liquid L and before raising the cover 50 from the processing position P1 to the standby position P2 (preferably, before initiating the supply of the rinsing liquid). After completing the supply of the processing liquid L, there is no need to heat the substrate W. By limiting the discharge flow rate of the gas after completing the supply of the processing liquid L, it is possible to reduce the usage of the gas.

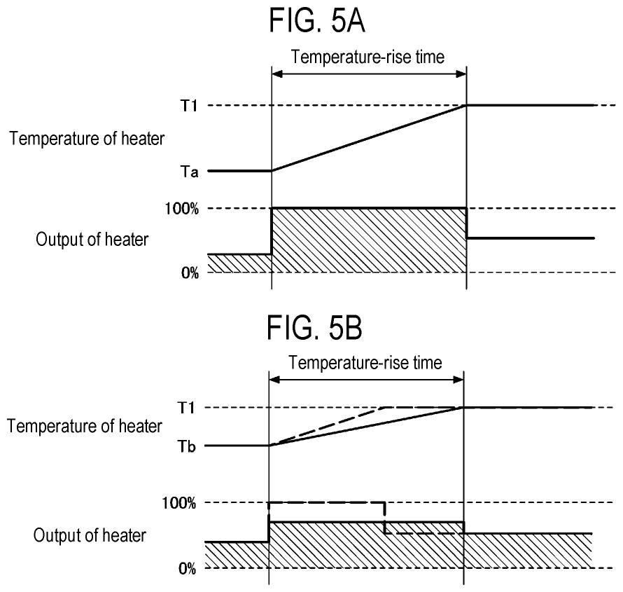

Next, an example of the control to raise the temperature of the heater 70 to the first set temperature T1 from temperatures Ta and Tb lower than the first set temperature T1 will be described with reference to FIGS. 5A and 5B. The control illustrated in FIGS. 5A and 5B may be performed for a time period illustrated by the dashed line C in FIG. 4. Alternatively, the control may be performed for a time period from when the substrate processing apparatus 1 is powered on until when the loading of the 1^{st} substrate W is completed.

As illustrated in FIGS. 5A and 5B, the controller 90 controls the output of the heater 70 to raise the temperature of the heater 70 at a preset specific temperature-rise time period regardless of the temperatures Ta and Tb (Ta<Tb) at the time of beginning a temperature raise. In a case where the temperature at the time of beginning a temperature raise is high, when such a temperature rise is performed at the same temperature-rise rate as that in a case where the temperature at the time of beginning a temperature raise is low, the temperature of the heater 70 may reach the first set temperature T1 too quickly, leading to an increase in the power consumption of the heater 70, as illustrated by the dashed line in FIG. 5B.

In the present embodiment, as described above, the controller 90 controls the output of the heater 70 to raise the temperature of the heater 70 at the preset specific temperature-rise time period regardless of the temperatures Ta and Tb (Ta<Tb) at the time of beginning a temperature raise. Thus, it is possible to maintain a time for which the temperature of the heater 70 reaches the first set temperature T1 constant, which makes it possible to reduce the power consumption of the heater 70.

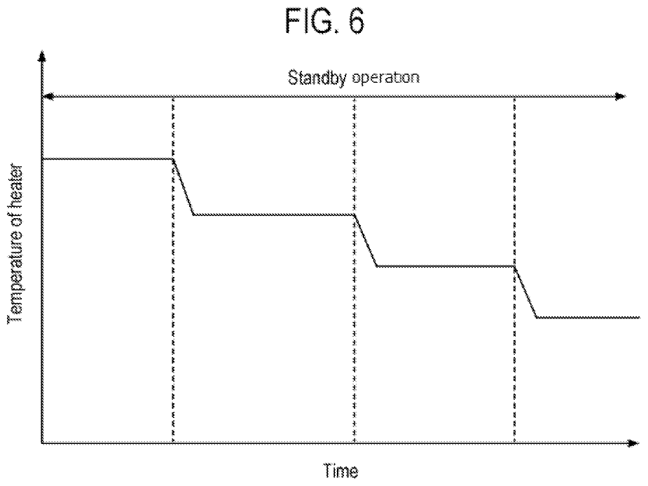

FIG. 6 is a cross-sectional view illustrating an example of a change in the first set temperature T1. As illustrated in FIG. 6, the controller 90 performs a control to lower the first set temperature T1 in a stepwise manner over time during the standby operation. That is, the controller 90 performs a control to lower the temperature of the heater 70 in a stepwise manner over time during the standby operation. Two or more (four in FIG. 6) temperatures are set in advance as the first set temperature T1. In a case where the standby operation becomes longer, it is possible to reduce the output of the heater 70 in a stepwise manner, which reduces the power consumption of the heater 70.

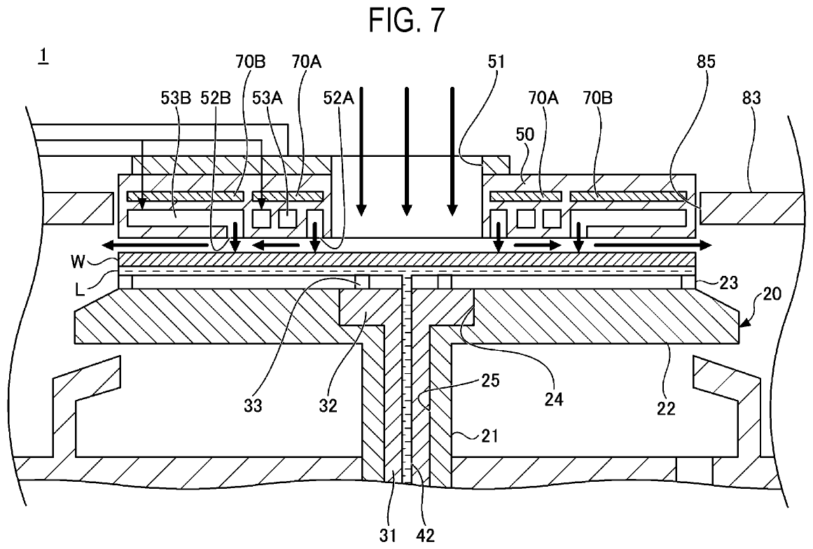

Next, a substrate processing apparatus 1 according to a first modification will be described with reference to FIG. 7. Hereinafter, differences between this modification and the above-described embodiment will be mainly described. A plurality of heaters 70A and 70B are provided along the radial direction of the substrate W. Hereinafter, the heater 70A may be referred to as a first heater 70A, and the heater 70B may be referred to as a second heater 70B.

The second heater 70B is provided outward of the first heater 70A in the radial direction of the substrate W. The first heater 70A heats the first gas flow path 53A. The second heater 70B heats the second gas flow path 53B. The controller 90 is capable of independently controlling outputs of the first heater 70A and the second heater 70B.

The controller 90 is capable of independently controlling the outputs of the plurality of heaters 70A and 70B. By independently controlling the outputs of the plurality of heaters 70A and 70B and dividing the substrate W into a plurality of regions in the radial direction, it is possible to provide an appropriate amount of heat to each region, which reduces the power consumption. In an embodiment, when the power consumption is low, one heater 70 may be used.

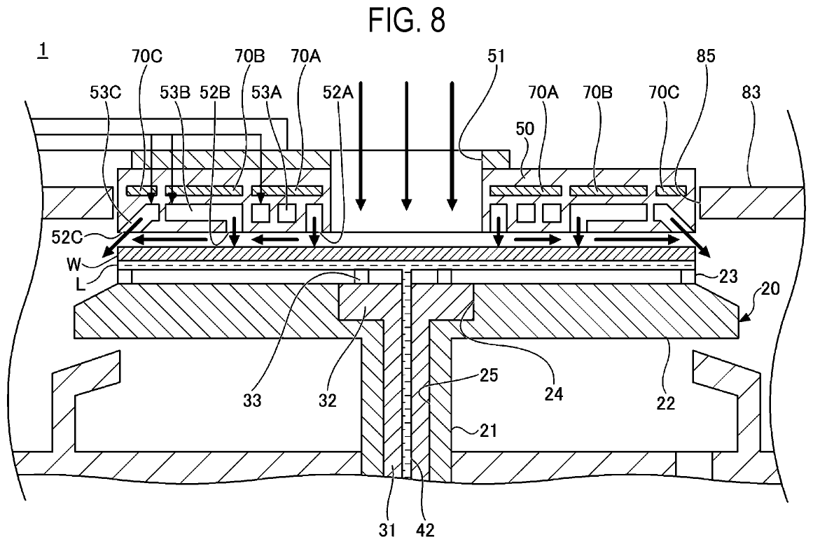

Next, a substrate processing apparatus 1 according to a second modification will be described with reference to FIG. 8. Hereinafter, differences between this modification and the above-described first modification will be mainly described. The cover 50 includes a third gas outlet 52C in addition to the first gas outlet 52A and the second gas outlet 52B. The third gas outlet 52C is located outward of the second gas outlet 52B in the radial direction of the substrate W. A plurality of third gas outlets 52C may be provided at equal intervals in the circumferential direction of the substrate W.

The third gas outlet 52C discharges the gas in an obliquely downward direction toward an outer peripheral portion of the substrate W. Specifically, the expression “obliquely downward direction: refers to a direction that is inclined outward in the radial direction of the substrate W as it goes downward. By discharging the gas in the obliquely downward direction toward the outer peripheral portion of the substrate W, it is possible to prevent the processing liquid L from flowing around the upper surface of the substrate W.

The cover 50 includes the third gas flow path 53C in addition to the first gas flow path 53A and the second gas flow path 53B. The third gas flow path 53C is provided outward of the second gas flow path 53B in the radial direction of the substrate W. The third gas outlet 52C is provided at a distal end of the third gas flow path 53C.

The substrate processing apparatus 1 includes a third heater 70C in addition to the first heater 70A and the second heater 70B. The third heater 70C is provided outward of the second heater 70B in the radial direction of the substrate W. The third heater 70C heats the gas flowing through the third gas flow path 53C.

The controller 90 is capable of independently controlling the outputs of the plurality of heaters 70A, 70B and 70C. By independently controlling the outputs of the plurality of heaters 70A, 70B and 70C and dividing the substrate W into a plurality of regions in the radial direction, it is possible to provide an appropriate amount of heat to each region, which reduces the power consumption.

According to a mode of the present disclosure, it is possible to prevent a reduction in processing efficiency of a substrate and reduce power consumption of a heater.

Although the embodiments of the substrate processing apparatus and the substrate processing method according to the present disclosure have been described above, the present disclosure is not limited to the above embodiments. Various changes, modifications, substitutions, additions, deletions, and combinations can be made within the scope of the claims. Of course, these also fall within the technical scope of the present disclosure.

What is claimed is:

1. A substrate processing apparatus comprising:
a processing container in which a loading/unloading port for a substrate is provided;
a substrate holder configured to horizontally hold the substrate inside the processing container;
a liquid supplier configured to supply a processing liquid to a lower surface of the substrate held by the substrate holder;
a cover provided with a gas outlet configured to discharge a gas toward an upper surface of the substrate held by the substrate holder;
a gas supplier configured to supply the gas to the cover;
a heater provided in the cover to heat the gas; and
a controller,
wherein the controller is configured to perform a control to:
maintain a temperature of the heater at a second set temperature higher than a first set temperature while the processing liquid is supplied to the lower surface of the substrate;
maintain the temperature of the heater at the first set temperature during a standby operation from when the substrate begins to be unloaded from the processing container until a subsequent substrate is loaded into the processing container; and
increase an output of the heater during the standby operation and raise the temperature of the heater from the first set temperature to the second set temperature until the subsequent substrate is loaded into the processing container.

2. The substrate processing apparatus of claim 1, wherein the liquid supplier is configured to supply, to the lower surface of the substrate held by the substrate holder, the processing liquid and a rinsing liquid for removing the processing liquid from the substrate in a sequential manner, and
wherein the controller is configured to perform the control to decrease the output of the heater after supplying the processing liquid and before supplying the rinsing liquid and lower the temperature of the heater kept at the second set temperature.

3. The substrate processing apparatus of claim 2, wherein the controller is configured to perform the control to increase the output of the heater within a set period of time from when the standby operation begins and return the temperature of the heater to the first set temperature.

4. The substrate processing apparatus of claim 1, wherein an opening is provided in a central portion of the cover so as to vertically pass through the cover, and
wherein the substrate processing apparatus includes a down-flow creator provided on a ceiling of the processing container.

5. The substrate processing apparatus of claim 1, wherein the controller is configured to perform the control to:
maintain a discharge flow rate of the gas at a second set flow rate higher than a first set flow rate while the processing liquid is supplied to the lower surface of the substrate;
maintain the discharge flow rate of the gas at the first set flow rate during the standby operation; and
increase the discharge flow rate of the gas from the first set flow rate to the second set flow rate while the temperature of the heater is raised from the first set temperature to the second set temperature.

6. The substrate processing apparatus of claim 5, further comprising: a lifter configured to raise and lower the cover between a processing position where the processing liquid is supplied to the lower surface of the substrate and a standby position above the processing position,
wherein the controller is configured to perform the control to lower the cover from the standby position to the processing position in a state where the discharge flow rate of the gas is maintained at the second set flow rate.

7. The substrate processing apparatus of claim 6, wherein the controller is configured to perform the control to lower the discharge flow rate of the gas from the second set flow rate to the first set flow rate after suppling the processing liquid and before raising the cover from the processing position to the standby position.

8. The substrate processing apparatus of claim 1, wherein the controller controls the output of the heater so that the temperature of the heater is raised to the first set temperature from a temperature lower than the first set temperature within a preset temperature-rise time period.

9. The substrate processing apparatus of claim 1, wherein the controller is configured to perform the control to lower the first set temperature in a stepwise manner over time during the standby operation.

10. The substrate processing apparatus of claim 1, wherein the gas outlet includes a plurality of gas outlets provided along a radial direction of the substrate,
wherein the heater includes a plurality of heaters provided along the radial direction of the substrate, and
wherein the controller independently controls outputs of the plurality of heaters.

11. A substrate processing method comprising processing a substrate using a substrate processing apparatus,
wherein the substrate processing apparatus includes:
a processing container in which a loading/unloading port for the substrate is provided;
a substrate holder configured to horizontally hold the substrate inside the processing container;
a liquid supplier configured to supply a processing liquid to a lower surface of the substrate held by the substrate holder;
a cover provided with a gas outlet configured to discharge a gas toward an upper surface of the substrate held by the substrate holder;
a gas supplier configured to supply the gas to the cover;
a heater provided in the cover to heat the gas; and
a controller,
wherein substrate processing method further comprises:
maintaining a temperature of the heater at a second set temperature higher than a first set temperature while the processing liquid is supplied to the lower surface of the substrate;
maintaining the temperature of the heater at the first set temperature during a standby operation from when the substrate begins to be unloaded from the processing container until a subsequent substrate is loaded into the processing container; and
increasing an output of the heater during the standby operation and raising the temperature of the heater from the first set temperature to the second set temperature until the subsequent substrate is loaded into the processing container.

12. The substrate processing method of claim 11, wherein the liquid supplier is configured to supply, to the lower surface of the substrate held by the substrate holder, the processing liquid and a rinsing liquid for removing the processing liquid from the substrate in a sequential manner, and
wherein substrate processing method further comprises decreasing the output of the heater after supplying the processing liquid and before supplying the rinsing liquid and lowering the temperature of the heater kept at the second set temperature.

13. The substrate processing method of claim 12, further comprising: increasing the output of the heater within a set period of time from when the standby operation begins and returning the temperature of the heater to the first set temperature.

14. The substrate processing method of claim 11, wherein an opening is provided in a central portion of the cover so as to vertically pass through the cover, and
wherein the substrate processing apparatus includes a down-flow creator provided on a ceiling of the processing container.

15. The substrate processing method of claim 11, further comprising:
maintaining a discharge flow rate of the gas at a second set flow rate higher than a first set flow rate while the processing liquid is supplied to the lower surface of the substrate;
maintaining the discharge flow rate of the gas at the first set flow rate during the standby operation; and
increasing the discharge flow rate of the gas from the first set flow rate to the second set flow rate while the temperature of the heater is raised from the first set temperature to the second set temperature.

16. The substrate processing method of claim 15, wherein the substrate processing apparatus further includes: a lifter configured to raise and lower the cover between a processing position where the processing liquid is supplied to the lower surface of the substrate and a standby position above the processing position,
wherein the substrate processing method further comprises: lowering the cover from the standby position to the processing position in a state where the discharge flow rate of the gas is maintained at the second set flow rate.

17. The substrate processing method of claim 16, further comprising: lowering the discharge flow rate of the gas from the second set flow rate to the first set flow rate after suppling the processing liquid and before raising the cover from the processing position to the standby position.

18. The substrate processing method of claim 11, further comprising: controlling the output of the heater so that the temperature of the heater is raised to the first set temperature from a temperature lower than the first set temperature within a preset temperature-rise time period.

19. The substrate processing method of claim 11, further comprising: lowering the first set temperature in a stepwise manner over time during the standby operation.

20. The substrate processing method of claim 11, wherein the gas outlet includes a plurality of gas outlets provided along a radial direction of the substrate,
wherein the heater includes a plurality of heaters provided along the radial direction of the substrate, and
wherein the substrate processing method further comprises: independently controlling outputs of the plurality of heaters.
